(19) United States
(12) Patent Application Publication
(10) Pub. No.: US 2024/0058893 A1
(43) Pub. Date: Feb. 22, 2024

(54) SYSTEMS AND METHODS OF FORMING A BRUSH TO CLEAN A SURFACE

(71) Applicant: Illinois Tool Works Inc., Glenview, IL (US)

(72) Inventors: Bradley Scott Withers, El Dorado Hills, CA (US); Corey Alan Hughes, Sacramento, CA (US); Erik Scott Nelson, Granite Bay, CA (US); Brent Allan Best, Rocklin, CA (US)

(21) Appl. No.: 18/449,086

(22) Filed: Aug. 14, 2023

Related U.S. Application Data
(60) Provisional application No. 63/399,387, filed on Aug. 19, 2022.

(51) Int. Cl. B23K 26/08; B23K 37/053

(52) U.S. Cl. CPC B23K 26/0823; B23K 37/053

(57) ABSTRACT

Systems and methods of forming a brush for advanced semiconductor contact cleaning applications are disclosed. For example, a contact surface or surfaces, such as a nodule, of a brush can be cut by a laser cutting system. The use of a laser cutting system allows for uniform cutting of the contact surface across a length of the brush.

### CROSS REFERENCE TO RELATED APPLICATIONS

This application is a Non-Provisional patent application of U.S. Provisional Patent Application No. 63/399,387 entitled “Systems And Methods Of Forming A Brush To Clean A Surface” filed Aug. 19, 2022, which is herein incorporated by reference in its entirety.

### BACKGROUND

The present disclosure relates to substrate-cleaning brushes, and more particularly, to systems and methods of forming a brush to clean a surface.

In the semiconductor manufacturing industry and other industries, brushes are used to remove contaminants from surfaces, such as from semiconductor wafers. Depending on the specific application, cleaning of a substrate or surface may also involve delivery of one or more substances (e.g., chemicals, ultra-pure water (UPW), deionized water (DIW), etc.) to the substrate or surface. However, some conventional methods of forming such brushes result in inconsistencies in the application surface, which can impact cleaning quality.

Limitations and disadvantages of conventional approaches to forming or conditioning brushes will become apparent to one of skill in the art, through comparison of such approaches with some aspects of the present method and system set forth in the remainder of this disclosure with reference to the drawings.

### SUMMARY

Systems and methods of forming a brush for contact cleaning applications are disclosed, substantially as illustrated by and described in connection with at least one of the figures, as set forth more completely in the claims.

### BRIEF DESCRIPTION OF THE DRAWINGS

These and/or other aspects will become apparent and more readily appreciated from the following description of the exemplary embodiments, taken in conjunction with the accompanying drawings.

FIG. 1 illustrates an example system to form a brush for contact cleaning applications, in accordance with aspects of this disclosure.

FIGS. 2A and 2B illustrate example views of a laser system cutting a nodule, in accordance with aspects of this disclosure.

FIGS. 3A and 3B illustrate multiple views of an example brush, in accordance with aspects of this disclosure.

FIGS. 4A and 4B illustrate multiple views of an example brush and nodules, in accordance with aspects of this disclosure.

FIGS. 5A and 5B illustrate multiple views of an example brush and nodules, in accordance with aspects of this disclosure.

FIGS. 6A and 6B illustrate examples of pre- and post-laser cut brushes, in accordance with aspects of this disclosure.

FIG. 7 provides an example graph comparing brush radius variability of an example as-molded brush and a brush cut by the disclosed laser system, in accordance with aspects of this disclosure.

FIGS. 8A and 8B illustrate example details of sample images of laser cut and mechanically cut nodule surfaces.

FIGS. 9A and 9B illustrate example details of sample images of laser cut and mechanically cut nodule surfaces.

FIGS. 10A and 10B provide views of two example brushes and nodules, in accordance with aspects of this disclosure.

FIGS. 11A and 11B illustrate a diagrammatic representation of nodules being cut by a laser process and a mechanical grinding process, in accordance with aspects of this disclosure.

FIGS. 12 and 13 illustrate example brushes with various cut patterns, in accordance with aspects of this disclosure.

FIG. 14 illustrates a flowchart representative of an example method of forming a brush by a laser cutting process, in accordance with aspects of this disclosure.

The figures are not necessarily to scale. Where appropriate, similar or identical reference numbers are used to refer to similar or identical components.

### DETAILED DESCRIPTION

Various applications and processes may benefit from physical cleaning of a surface. For example, in semiconductor manufacturing, a semiconductor wafer may be cleaned to remove potentially destructive contaminants during one or more stages of fabricating microelectronic devices on the wafer. The cleaning can be provided by, for example, a brush that comes in contact with the surface to be cleaned.

To efficiently clean a substrate, disclosed example brushes come into contact with a substrate to be cleaned in the presence of a fluid (e.g., a cleaning chemical). Conventional brushes are either mounted or cast directly to rotatable hollow bases or mandrels, with holes that allow water, a chemical, or both to flow through the base or mandrel, into and through the brush body, and onto the substrate or wafer to be cleaned.

Due to the construction of conventional disk and/or roller brushes, conventional brushes may not be uniformly even across the application surface. This may cause the application surface to not be sufficiently cleaned, generate debris, and/or cause defects on the surface.

Thus, systems and methods of forming a brush for advanced semiconductor contact cleaning applications are disclosed. In particular, a contact surface or surfaces, such as a nodule, of a brush can be cut by a laser cutting system. The use of a laser cutting system avoids many of the issues associated with mechanical cutting or surface abrasion, such as deformation of the nodules, uneven contact surfaces, and/or inherent variability of the nodule surface for varying shapes and aspect ratios, important for unique applications. Further, application of a fluid and/or pre-wetting the brush avoids burning, discoloration of the brush, and thereby damage to the surface. The laser cutting system also allows for a quick and consistent cut of the surface (e.g., nodules), further preventing issues commonly associated with application of laser power.

In some examples, the brush is formed of Polyvinyl Acetal (PVA) suitable for advanced semiconductor cleaning applications, including but not limited to post-Chemical Mechanical Planarization (CMP) cleaning. Disclosed methods employ a computer numerical control (CNC) system with a Carbon Dioxide (CO₂) laser to cut, trim, shape, or otherwise alter one or more surfaces of one or more protrusions or nodules of the brush.

In disclosed examples, a method of forming a brush to clean a surface includes forming a brush with a plurality of nodules extending from a surface of the brush, the brush having a mandrel extending through the brush; and cutting, via a laser system, the plurality of nodules to a predetermined distance from a central axis of the brush.

In some examples, the method includes rotating the brush about the central axis to align a nodule of the plurality of nodules with a beam of the laser system.

In some examples, the method includes moving the laser system along a surface of the brush to align a beam of the laser system with a nodule of the plurality of nodules.

In examples, the cutting via the laser system creates a planar surface on the plurality of nodules that is tangential to a radius extending the predetermined distance from the central axis.

In examples, the cutting via the laser system creates an angled surface on the plurality of nodules relative to a plane tangential to a radius extending the predetermined distance from the central axis.

In some examples, the method includes a length of the brush is defined by a first portion and a second portion, wherein the cutting via the laser system comprises cutting the plurality of nodules at the predetermined distance along the first portion and cutting the plurality of nodules at a second predetermined distance along the second portion.

In some examples, the method includes channeling fluid through the brush during the cutting.

In some disclosed examples, a system for forming a brush to clean a surface includes a mandrel to mount a brush that includes a plurality of nodules extending from a surface of the brush; and a laser system to cut the plurality of nodules to a predetermined distance from a central axis of the brush.

In some examples, the system includes a guide to depress, deform, or move a first nodule of the plurality of nodules as the laser system cuts a second nodule of the plurality of nodules. In examples, the brush has a cylindrical shape and is defined by a first portion and a second portion along a length of the cylindrical brush, the first portion having a first diameter and the second portion having a second diameter larger than the first diameter. In examples, the first portion corresponds to a central portion of the length of the brush, and the second portion corresponds to an edge of the brush.

In some examples, the system includes an inlet to channel fluid from a fluid source through the brush and the plurality of nodules to maintain a threshold amount of moisture in the brush as the laser system cuts the plurality of nodules.

In some examples, the system includes a computer numerical control (CNC) machine to secure and move one or both of the brush or the laser system.

In examples, the brush is formed of Polyvinyl Acetal (PVA). In examples, the laser system comprises a CO₂ laser source.

In some disclosed examples, a system for forming a brush to clean a surface includes a mandrel to mount a brush that includes a contact surface; a laser system to cut the one or more patterns into the contact surface; and an inlet to channel fluid from a fluid source through the brush and the contact surface to maintain a threshold amount of moisture in the brush as the laser system cuts the contact surface.

In some examples, the laser system selectively cuts two or more portions of the contact surface to remove a desired amount of a skin layer on the contact surface at the two or more portions.

In some examples, the two or more portions comprise a plurality of nodules, the brush configured to rotate about a central axis to align a nodule of the plurality of nodules with a beam of the laser system. In examples, the laser system is configured to move along the contact surface to align a beam of the laser system with a nodule of the plurality of nodules.

In some examples, the laser system comprises a CO₂ laser source to generate a beam to cut the contact surface.

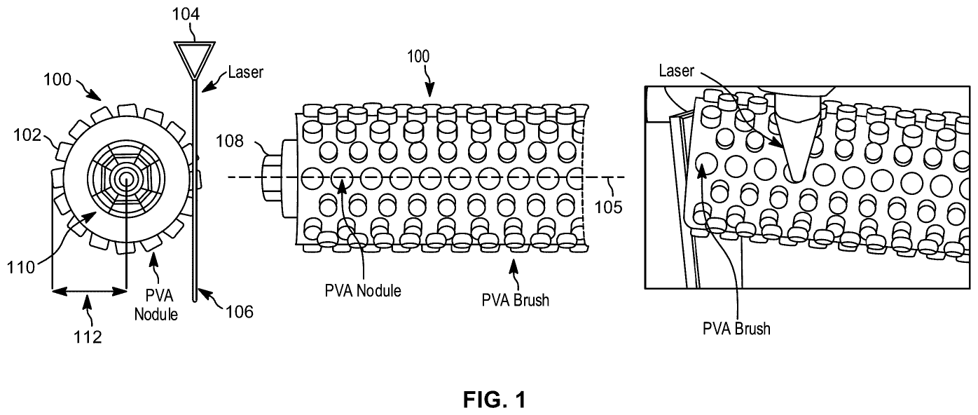

As provided in FIG. 1, a brush 100 can be suspended on a fixture (e.g., a mandrel 108 or other support 108) configured to rotate about an axis 105. For example, the brush 100 is molded or otherwise formed onto the mandrel 108. In some examples, the brush 100 is formed separately and then mounted to a mandrel 108. The brush 100 is defined by a brush body 110 with one or more nodules 102 extending therefrom. The nodules 102 are to be placed in contact with a substrate (e.g., a surface) to clean and/or polish the substrate. The example brush 100 is a porous polymeric foam, which may be molded, machined, constructed using additive manufacturing techniques, and/or otherwise constructed in an annular and/or cylindrical shape. Example polymeric foams that may be used to implement the brush 100 include polyvinyl acetate foams, polyurethane foams, polyolefin foams, porous fluoropolymers, and/or silicone foams.

To achieve a desired, consistent radial diameter, the one or more nodules 102 can be cut by a laser beam 106 from a laser system 104, as the brush 100 rotates about the axis 105. Further, the laser system 104 (or the brush 100) can translate along the axis 105 to cut nodes 102 arranged at different locations on the brush 100. The laser power from the laser system 104 can be applied over a range of values (e.g., approximately 100 Watts to 500 Watts) at a variety of cutting speeds. The applied laser power and/or cutting speed can be selected based on a number of factors, including nodule shape, material density, number of nodules to be cut, number of cuts per nodule, as a list of non-limiting factors.

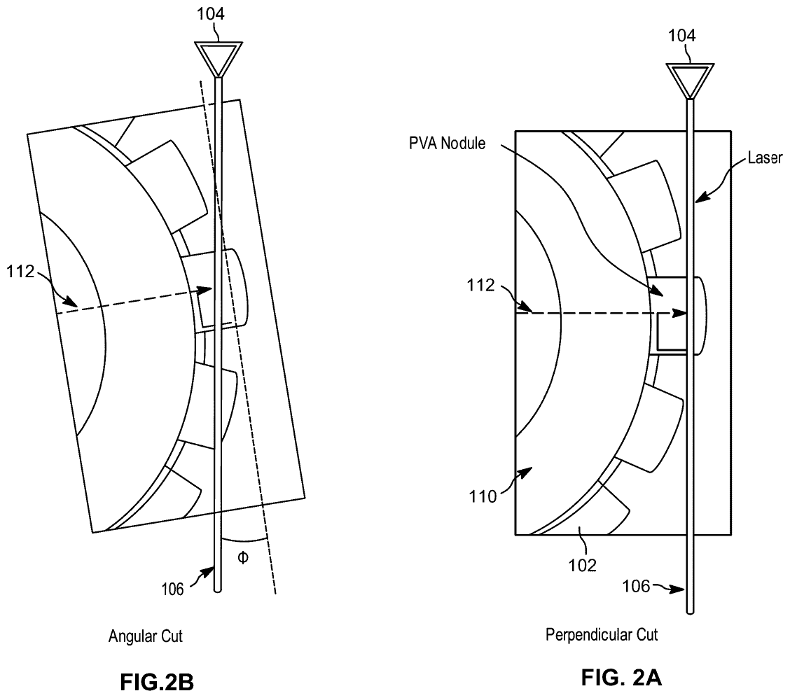

In some examples, motion of an associated CNC system controls a depth of each cut relative to the rotational axis 105 of the brush 100, such that each cut is a predetermined radius 112 of the brush 100. As shown in FIGS. 2A and 2B, the brush 100 can be moved relative to the laser system 104 and/or the laser beam 106 (e.g., rotated, moved in one or more of an X-Y-Z plane) in order to control an angle of the cut. Parameters of a pre-programmed cutting operation can control movement of the laser system 104 (and/or the brush 100) to cut a row of nodules 102, for example, and can then rotate the brush (and/or laser system 104) to process (e.g., cut) another row, such as an adjacent row, of nodules around the periphery of the brush.

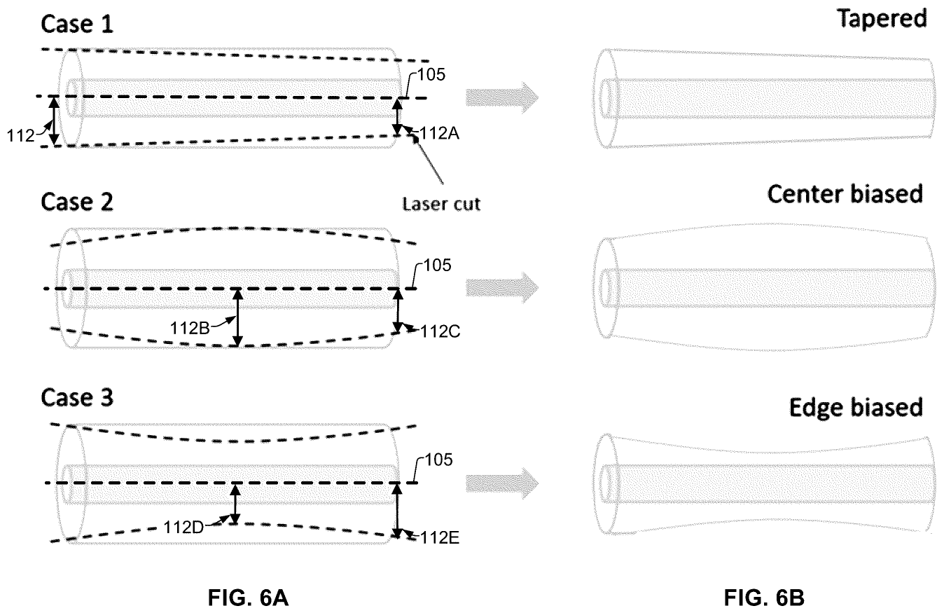

In the example of FIG. 2A, the laser beam 106 cuts a nodule at a 90 degree angle relative to the radius 112. FIG. 2B illustrates a cut of one or more nodules at an angle Φ relative to the radius 112 at the given nodule. Although shown as a single cut being performed for a flat external surface of the nodule, in some examples multiple cuts can be performed such that the external surface of the nodule presents a varied surface to a surface to be cleaned. Moreover, nodules of a first portion of the brush may have present a first cut or cuts, whereas nodules of a second portion may present a second cut or cuts. The portions may be linear (e.g., along a length of the brush), radial (e.g., along a circumference of the brush), and/or be split at any number of areas along an outer surface of the brush, depending on the surface to be cleaned (see, e.g., FIGS. 6A and 6B).

In some examples, during a laser cutting operation one or more nodules may be depressed, reoriented, and/or otherwise moved to avoid cutting a nodule unnecessarily. For example, a mechanical device (e.g., paddle, plate, guide, etc.) can be used to compress the foam of a given nodule to remove it from the path of the laser beam while cutting another nodule.

During an example cutting operation, the brush 100 is kept moist to prevent staining, burning, deformation, and/or other damage to the PVA material. The moisture level can range from light saturation (e.g., 5% weight) to approximate full saturation (e.g., ˜300% weight). The moisture agent can be any suitable fluid (e.g., water or chemical solution), with the brush pre-wetted prior to cutting. In some examples, a fluid can be passed through the brush 100 during the cutting process if reasonably constant, but full saturation is desired.

Although disclosed examples describe the use of PVA-based foam materials for advanced semiconductor cleaning applications, this technology and resulting brush structures can be extended to any porous polymeric cleaning products (e.g., polyurethane, polyolefin, polyester, porous fluoropolymers, etc.). Example brushes may be configured with different geometries, including shaped nodules, cut by the disclosed systems and methods, extending from the brush body to make contact with the surface. In some examples, the contact surfaces are configured with microtextures to achieve one or more tribological effects.

As used herein, chemicals or process chemicals may refer to any substance that may be applied via disclosed brushes, including water such as deionized water (DIW) and/or ultrapure water (UPW).

Disclosed examples brushes may include an annular porous polymeric brush body configured to rotate about an axis during cutting. In some examples, the brush is constructed via at least one of molding, machining, or additive manufacturing.

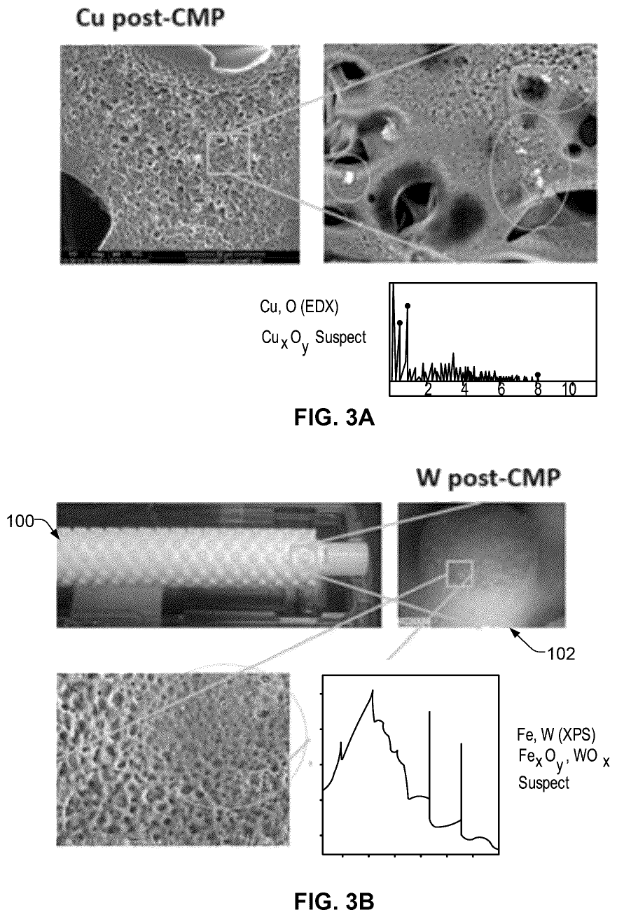

Some conventionally molded foam products are produced with a “skin” or film layer on the surface of the part. For post-CMP applications and other critical contact semiconductor cleaning processes, the surface energy of the skin layer readily traps unwanted process debris, as shown in FIGS. 3A and 3B. The process debris often agglomerates on the nodule surface, which can lead to scratching or cross-contamination of the surface to be cleaned. For many semiconductor contact cleaning applications, for instance, such defects can result in damage to the die and/or yield loss.

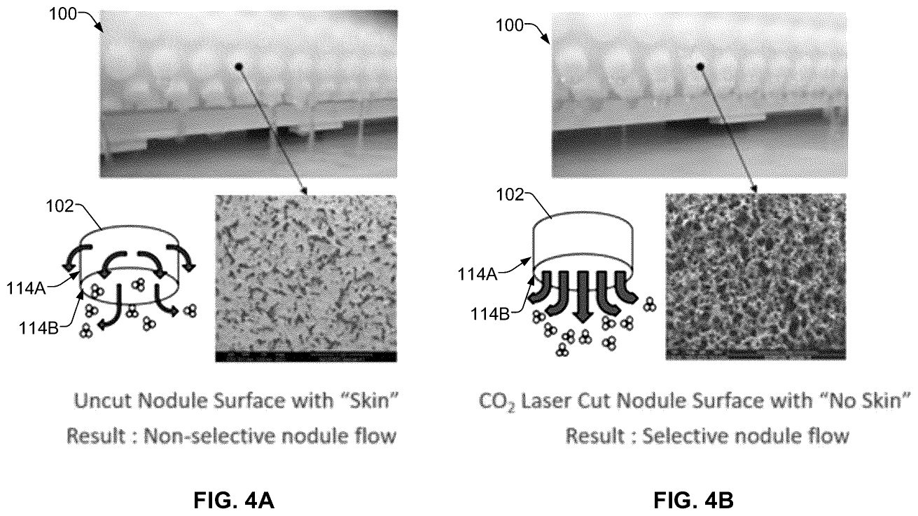

As shown in FIG. 4A, a given nodule 102 with an approximately uniform skin layer on a side surface 114A and a contact surface 114B results in fluid flowing through both nodule surfaces. The disclosed laser cutting process provides a quick and efficient way to remove the skin layer from molded polymeric foams like PVA, while also cutting the nodules to meet the desired brush diameter. Removing the skin layer from the surface of the brush (e.g., the nodule surface) has the effect of lowering the surface energy of the nodule, provides a porous surface that is less likely to trap process debris, and/or allows for easy flushing (e.g., in-situ cleaning) of the brush. For example, fluid that flows through a molded polymeric foam tends to travel a path of least resistance. A skin layer can impede that flow. However, with a cut at one of the surface of the brush, such as an open contact surface 114B of the nodule, fluid will flow selectively through the contact surface 114B rather than the side surface 114A, thereby hydrodynamically forcing debris away from the nodule contact surface, as shown in FIG. 4B.

In some foam molding operations, the consistency and uniformity of the product, including the external dimensions, is dependent on the precision of the mold, mold assembly, molding process conditions, demold process, and/or variability of the raw material being used. The disclosed laser cutting system and/or process allows for control of the shape and/or size of the brush 100 and roller assembly, independent of most factors that lead to poor molded product quality, in particular, dimensional control.

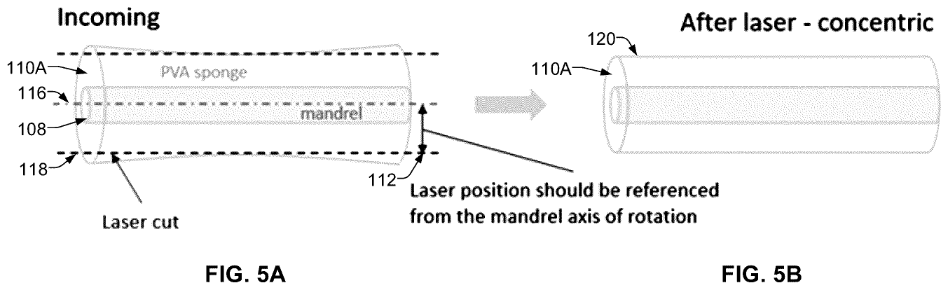

For conventional roller brushes, a laser cut line can be placed at a radial distance 112 referenced from the brush axis-of-rotation 116 to produce a concentric roller with desired dimensions from an otherwise imperfectly molded product, as shown in FIG. 5A. A substantially uniform concentric roller brush (e.g., formed of PVA) provides for maximum nodule-substrate contact and therefore a more efficient cleaning process.

When a cleaning process calls for biased brush contact on a substrate, the laser system can also be configured to easily contour, profile, and/or produce non-concentric brushes. For example, three cases are illustrated in FIGS. 6A and 6B. A standard laser cutting operation may be one where a contact surface of each nodule has a similar radius measured from a central axis (e.g., as shown in FIGS. 5A and 5B). In the alternative example of Case 1, a first radius 112 from axis 105 is maintained at a first end of a brush, as the laser cut slopes to a second radius 112A at a second end, resulting in a tapered brush. In the example of Case 2, a central portion of the brush has a first radius 112B, larger than a second radius 112C at the ends of the brush, resulting in a center biased brush. In the example of Case 3, a first radius 112D at a central portion of the brush is smaller than a second radius 112E at the ends of the brush, resulting in an edge biased brush. Such alternative geometries may be particularly useful for advanced cleaning applications that are sensitive to brush over-compression and/or have cleaning/defect requirements that vary from center-to-edge along the length of the brush (e.g., metal post-CMP applications).

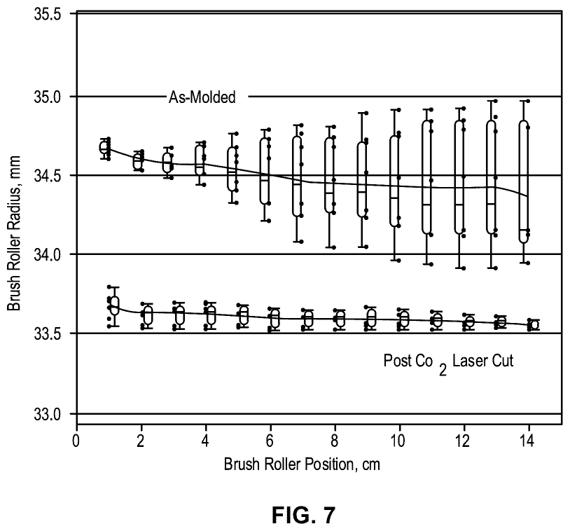

FIG. 7 provides an example graph comparing brush radius variability of an example as-molded brush and a brush cut by the disclosed laser system, in accordance with aspects of this disclosure. As shown, the variation of brush roller radius varies widely in the as-molded brush. By contrast, the post laser cut brush has a generally consistent brush roller radius.

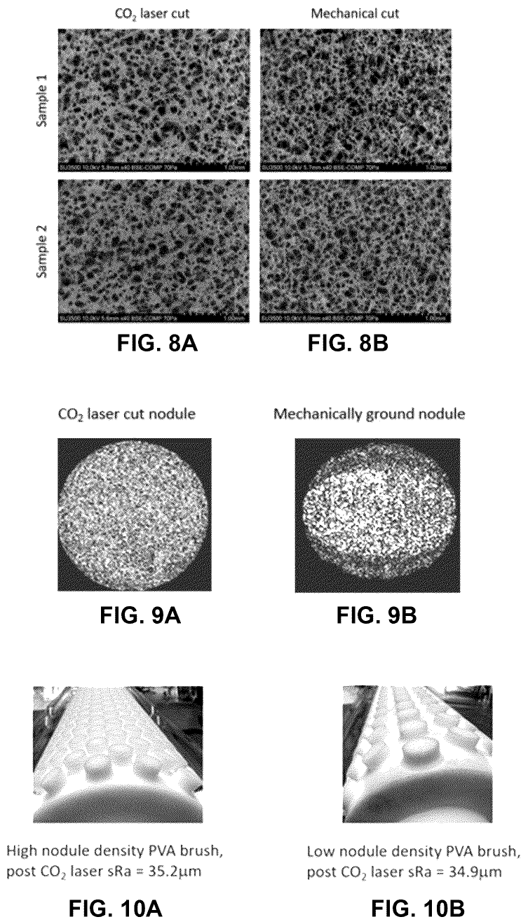

The disclosed laser cutting systems and methods can provide a surface equivalent to that of a mechanically cut surface. FIG. 8A to 10B show the quality of a brush and/or nodule surface processed by the disclosed laser cutting operation in comparison to a mechanically cut surface. The cut quality, or surface morphology, is typically measured by a non-contact roughness gage (via interferometry, for example) or qualitatively by a scanning electron microscope image, as provided in FIGS. 8A and 8B. The surface morphology of the cut surface is dependent on the mean pore size and porosity (e.g., pore distribution) of the material being cut.

Conventional mechanical cutting and/or grinding of the nodule can be challenging. For instance, the porous polymeric nodule material is flexible, so as the mechanical forces associated with blade cutting and/or grinding are applied to the nodule, the cut surface can become deformed and/or fail to cut and/or remove the skin layer from the entire nodule surface, as shown in FIG. 9B. Mechanically compliant PVA brush nodules that are ground will contour the nodule contact surface, altering the shape of the as-molded feature. As shown in FIG. 9A, because there is little or no distortion of the nodule during the laser cutting process, the entire nodule surface can be removed in a single pass without deforming the nodule, thereby resulting in a shape similar to that of the nodule/feature as-molded.

Another advantage of the laser cutting systems and methods is that the cut quality is independent of the nodule geometry, size, and/or density. For instance, there are many different post-CMP cleaning applications. Depending on the nature of the surface to be cleaned (e.g., metal or dielectric) and defect tolerance, brushes with different nodule designs/configurations may be required for a specific application. Unlike grinding processes that rely heavily on compression, process speeds, contact area, and other tribological phenomena, the laser cutting process is more consistent. Smaller diameter, high nodule density brushes (as shown in FIG. 10A) result in the same cut quality (e.g., morphology) as larger, lower nodule density brushes (as shown in FIG. 10B).

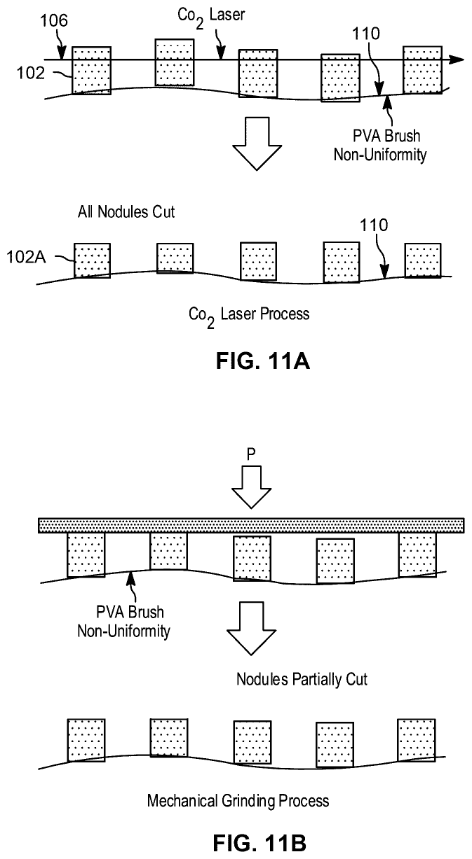

The grinding process is also heavily dependent on the uniformity of the molded brush. For example, brushes that are more uniform will grind more evenly. Brushes that are less uniform typically exhibit areas on the same brush that are sufficiently ground (e.g., open contact surfaces) and areas that are not sufficiently ground, and/or varying nodule profiles due to variable contact pressures against the brush during a grinding operation, as shown in FIG. 11B. The resulting variations in brush cut/morphology yields a non-ideal cleaning brush. By contrast, the disclosed laser systems and process compensate for incoming brush non-uniformity by adjusting the depth of cut, without process modification as shown in FIG. 11A).

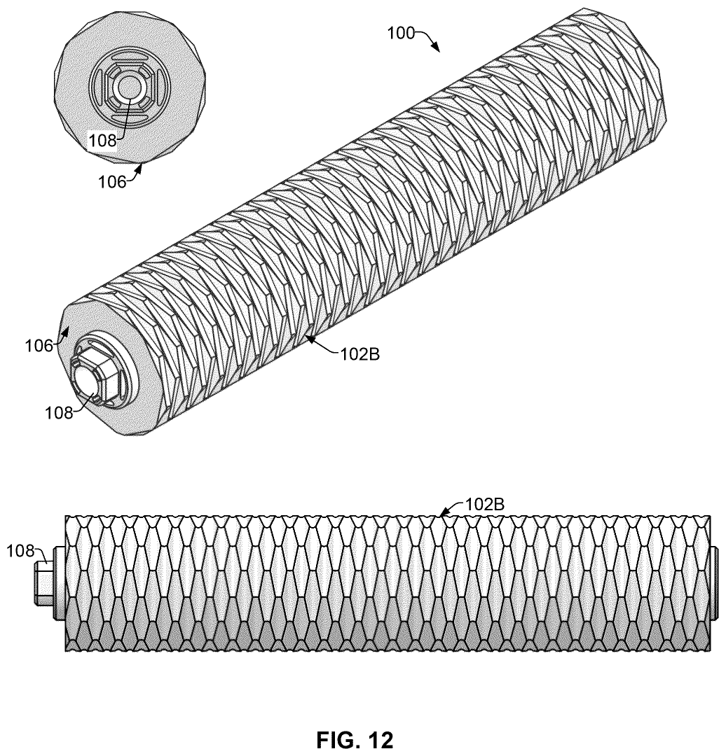

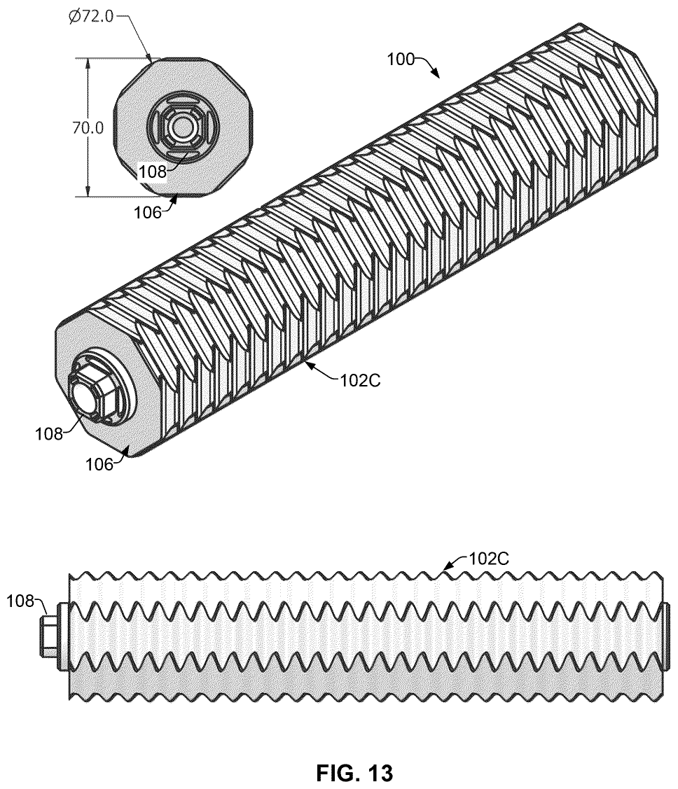

FIG. 12 illustrates a brush 100 with an example patterned contact surface 102B. FIG. 13 illustrates another example patterned contact surface 102C. In such examples, the brush itself may be molded with or without any nodule or protrusions. The laser cutting systems and methods may be configured to cut patterns, designs, and/or other variations on the surface of the brush. In some examples, the brush can include multiple portions or regions, each with a specific contact surface. As a non-limiting example, a first portion may be defined by nodules and/or patterns of a first size, geometry and/or density, whereas a second portion may be defined by a nodules and/or patterns of a second size, geometry and/or density. The portions may alternate, be unique, be adjacent, extend along a length of the brush, around a circumference of the brush, or any arrangement about the brush to suit the desired cleaning application. The size, geometry, and/or location of the multiple cuts can be designed to regulate flow of a liquid through a surface of brush body.

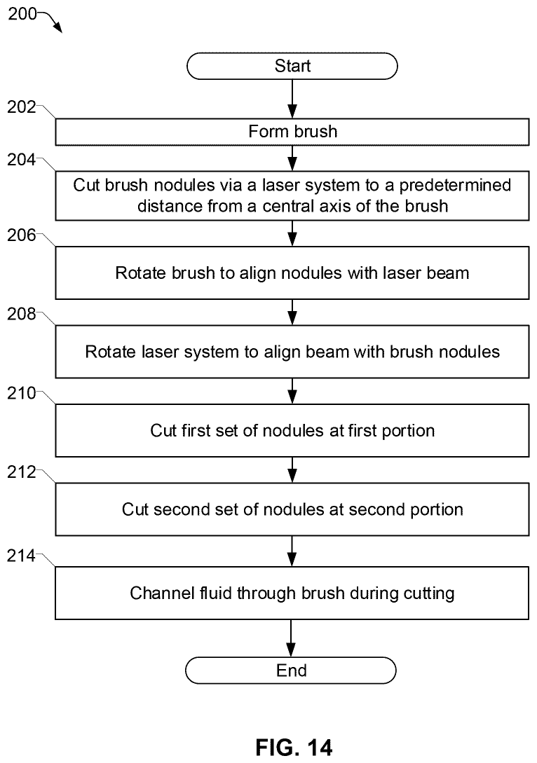

FIG. 14 illustrates a flowchart representative of an example method 200 method of forming a brush to clean a surface. At block 202, a brush is formed with a plurality of nodules extending from a surface of the brush. The brush body may be constructed by at least one of molding, machining, additive manufacturing (e.g., three-dimensional printing), and/or any other manufacturing techniques, either separately or in combination. In some examples, the brush is formed of a smooth surface (e.g., without nodules), and can be cut to have a variety of patterns. In some examples, the brush can be formed with a mandrel extending therethrough.

At block 204, the plurality of nodules are cut via a laser system to a predetermined distance from a central axis of the brush.

At block 206, the brush can be rotated about the central axis to align a nodule of the plurality of nodules with a beam of the laser system (e.g., with the laser beam position being maintained relative to the brush, or the laser beam position moved relative to the brush).

At block 208, the laser system is moved along a surface of the brush to align a beam of the laser system with a nodule of the plurality of nodules (e.g., with the brush position being maintained relative to the laser beam, or the brush position moved relative to the laser beam).

As disclosed herein, the cutting via the laser system can creates a planar surface on the plurality of nodules that is tangential to a radius extending the predetermined distance from the central axis, and/or create an angled surface on the plurality of nodules relative to a plane tangential to a radius extending the predetermined distance from the central axis.

At block 210, the laser system optionally cuts a first set of nodules at the predetermined distance along a first portion of the brush, and/or cuts a second set of nodules at a second predetermined distance along the second portion at block 212.

At block 214, fluid is optionally channeled through the brush during the cutting.

While example microtextures and patterns are illustrated in FIGS. 10A-10C, the microfeature shapes, concentrations or densities of features, microfeature sizes, microfeature depths, and/or any other geometrical aspect of the microfeatures may be modified to obtain the desired cleaning effects, unique tribological functions (e.g., enhanced lubrication, increased friction, improved cleaning efficiency), and/or different flow characteristics. Different portions of the brush body 110 and/or different nodules 102 may have different microtexturing features or properties. The same or different microtexturing may be used with different shapes of the disclosed nodules. The features and/or properties of the microtexturing may be selected based on the types of cleaning process.

The present methods and systems may be realized in hardware, software, and/or a combination of hardware and software. The present methods and/or systems may realize, for example, the control circuitry in a centralized fashion in at least one computing system, or in a distributed fashion where different elements are spread across several interconnected computing systems. Any kind of computing system or other apparatus adapted for carrying out the methods described herein is suited. A typical combination of hardware and software may include a general-purpose computing system with a program or other code that, when being loaded and executed, controls the computing system such that it carries out the methods described herein. Another typical implementation may comprise one or more application specific integrated circuit or chip. Some implementations may comprise a non-transitory machine-readable (e.g., computer readable) medium (e.g., FLASH memory, optical disk, magnetic storage disk, or the like) having stored thereon one or more lines of code executable by a machine, thereby causing the machine to perform processes as described herein. As used herein, the term “non-transitory machine-readable medium” is defined to include all types of machine readable storage media and to exclude propagating signals.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or.” As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, the present method and/or system are not limited to the particular implementations disclosed. Instead, the present method and/or system will include all implementations falling within the scope of the appended claims, both literally and under the doctrine of equivalents.

1. A method of forming a brush to clean a surface, the method comprising:
forming a brush with a plurality of nodules extending from a surface of the brush, the brush having a mandrel extending through the brush; and
cutting, via a laser system, the plurality of nodules to a predetermined distance from a central axis of the brush.

2. The method of claim 1, further comprising rotating the brush about the central axis to align a nodule of the plurality of nodules with a beam of the laser system.

3. The method of claim 1, further comprising moving the laser system along a surface of the brush to align a beam of the laser system with a nodule of the plurality of nodules.

4. The method of claim 1, wherein the cutting via the laser system creates a planar surface on the plurality of nodules that is tangential to a radius extending the predetermined distance from the central axis.

5. The method of claim 1, wherein the cutting via the laser system creates an angled surface on the plurality of nodules relative to a plane tangential to a radius extending the predetermined distance from the central axis.

6. The method of claim 1, wherein a length of the brush is defined by a first portion and a second portion, wherein the cutting via the laser system comprises cutting the plurality of nodules at the predetermined distance along the first portion and cutting the plurality of nodules at a second predetermined distance along the second portion.

7. The method of claim 1, further comprising channeling fluid through the brush during the cutting.

8. A system for forming a brush to clean a surface, the system comprising:
a mandrel to mount a brush that includes a plurality of nodules extending from a surface of the brush; and
a laser system to cut the plurality of nodules to a predetermined distance from a central axis of the brush.

9. The system of claim 8, further comprising a guide to depress, deform, or move a first nodule of the plurality of nodules as the laser system cuts a second nodule of the plurality of nodules.

10. The system of claim 8, wherein the brush has cylindrical shape and is defined by a first portion and a second portion along a length of the cylindrical brush, the first portion having a first diameter and the second portion having a second diameter larger than the first diameter.

11. The system of claim 10, wherein the first portion corresponds to a central portion of the length of the brush, and the second portion corresponds to an edge of the brush.

12. The system of claim 8, further comprising an inlet to channel fluid from a fluid source through the brush and the plurality of nodules to maintain a threshold amount of moisture in the brush as the laser system cuts the plurality of nodules.

13. The system of claim 8, further comprising a computer numerical control (CNC) machine to secure and move one or both of the brush or the laser system.

14. The system of claim 8, wherein the brush is formed of Polyvinyl Acetal (PVA).

15. The system of claim 8, wherein the laser system comprises a CO₂ laser source.

16. A system for forming a brush to clean a surface, the system comprising:
a mandrel to mount a brush that includes a contact surface;
a laser system to cut one or more patterns into the contact surface; and
an inlet to channel fluid from a fluid source through the brush and the contact surface to maintain a threshold amount of moisture in the brush as the laser system cuts the contact surface.

17. The system of claim 16, wherein the laser system selectively cuts two or more portions of the contact surface to remove a desired amount of a skin layer on the contact surface at the two or more portions.

18. The system of claim 16, wherein the two or more portions comprise a plurality of nodules, the brush configured to rotate about a central axis to align a nodule of the plurality of nodules with a beam of the laser system.

19. The system of claim 18, wherein the laser system is configured to move along the contact surface to align a beam of the laser system with a nodule of the plurality of nodules.

20. The system of claim 16, wherein the laser system comprises a CO₂ laser source to generate a beam to cut the contact surface.
